(19) United States
(12) Patent Application Publication
(10) Pub. No.: US 2015/0296624 A1
(43) Pub. Date: Oct. 15, 2015

(54) PRINTED CIRCUIT BOARD FOR MOUNTING CHIP AND METHOD OF MANUFACTURING THE SAME

(71) Applicant: LG INNOTEK CO., LTD., Seoul (KR)

(72) Inventors: Yun Ho An, Seoul (KR); Won Suk Jung, Seoul (KR); Ran Kim, Seoul (KR); Sung Soo Park, Seoul (KR); Young Joon Son, Seoul (KR); Sang Myung Lee, Seoul (KR); Woo Young Lee, Seoul (KR); Joon Wook Han, Seoul (KR)

(21) Appl. No.: 14/438,660

(22) PCT Filed: May 9, 2013
(86) PCT No.: PCT/KR2013/004106

§ 371 Date: Apr. 27, 2015

(30) Foreign Application Priority Data
Oct. 30, 2012 (KR) 10-2012-0121205

(51) Int. Cl. H05K 1/18

(52) U.S. Cl. CPC H05K 1/185; H05K 2201/09136; H05K 2201/095

(57) ABSTRACT

A printed circuit board for mounting a chip includes: a core layer including a chip mounting cavity; a chip mounted into the chip mounting cavity; a first insulating material layer filled in a space between the chip mounting cavity and the chip; and a second insulating material layer laminated on one surface of the core layer.

### TECHNICAL FIELD

The present invention relates to a method of manufacturing a printed circuit board for mounting a chip.

This application claims priority to Korean Patent Application No. 10-2012-0121205, filed on 30 Oct. 2012, in the Korean Intellectual Property Office, the entire contents of which are hereby incorporated by reference.

### BACKGROUND ART

As the miniaturization and high functionalization of electronic components have been realized according to the development of the electronics industry, a demand for the miniaturization and high density of a printed circuit board has been increasing steadily. According to the trend of lightened, thinned, shortened and small-sized electronic products, the printed circuit board has been also micro-patterned, miniaturized and packaged. A chip including an active device such as an IC and a passive device such as a condenser, resistor and the like was mounted on the surface of a conventional printed circuit board for packaging using a device such as a chip mounter.

However, in the past, the number of the chip mounted on a surface of the printed circuit increased in a certain number, and thus an area in which the chip is mounted was reduced from the surface of the printed circuit board. Accordingly, it was problematic that the printed circuit board is restricted by a mounting space of the chip mounted to the surface of the printed circuit board. Accordingly, an embedding process for equipping the chip in the printed circuit board has been recently developed and widely used.

FIG. 1 and FIG. 2 are cross-sectional views illustrating a printed circuit board for mounting a chip according to a conventional art.

Referring to FIG. 1, a printed circuit board for mounting a chip is configured such that a circuit pattern layer 20 is formed by forming Cu on both surfaces of a core layer 10 of an epoxy-based resin, and a chip mounting cavity, which passes through the core layer 10 and a circuit pattern layer 20, is formed. When a chip 30 is mounted to the chip mounting cavity, an insulating material layer 40 and a second circuit pattern layer 50 are formed on one surface of the core layer 10. accounts for an increasing volume compared to a volume of the printed circuit board, it is problematic that a total volume increases because a resin material should be filled in an inner part of the chip mounting cavity.

Also, as shown in FIG. 2, in the printed circuit board for mounting the chip, the insulating material layer 40 formed on one surface of the core layer 10 generates a difference in thickness according to its positions A, B thereof wherein ‘A’ is an area in which the chip 30 is mounted to the chip mounting cavity and ‘B’ is an area in which the insulating material layer 40 is in contact directly with the circuit pattern layer 20. Even after the chip 30 is mounted to the chip mounting cavity, a little space 10a is left in the chip mounting cavity. Accordingly, a difference in thickness is not generated from the areas A, B until the insulating material layer 40 is hardened (200) after the insulating material layer 40 is formed, but after the insulating material layer 40 is hardened (220), a difference in thickness is generated from the area A, B.

The reason why is because a phenomenon in which a total volume is reduced is generated when the insulating material layer 40 is formed on one surface the core layer 10 through a high temperature and a high pressure, and resin molecules of the insulating material layer 40 are aggregated to each other. When the difference in thickness of the insulating material layer 40 is generated, a warpage problem is generated due to the generation of stress.

### DISCLOSURE OF INVENTION

### Technical Problem

An aspect of the present invention provides a printed circuit board for mounting a chip, and a method of manufacturing the same, which is configured such that a first insulating material layer is formed on a core layer, and a second material layer of a different kind from that of the first insulating material layer is formed on one surface of the core layer so that the second insulating material layer is prevented from being non-uniformly formed on the surface of the core layer, thereby minimizing the generation of warpage.

Another aspect of the present invention provides a printed circuit board for mounting a chip, and a method of manufacturing the same, which is configured such that a first insulating material layer composed of only resin without glass fabric is thermal-compressed on one surface of a core layer so that a second material layer formed on the core layer can be uniformly formed on the surface of the core layer.

Still another aspect of the present invention provides a printed circuit board for mounting a chip, and a method of manufacturing the same, which is configured such that a first insulating material layer is formed on one surface of a core layer in advance so that a first insulating material layer is filled in a space formed between the chip and a chip mounting cavity in a core layer, whereby thicknesses from a second insulating material to another surface of the core layer in an area in which the chip mounting cavity is formed and an area in which the chip mounting cavity is not formed are formed to be substantially identical to each other.

Still another aspect of the present invention provides a printed circuit board for mounting a chip, and a method of manufacturing the same, which is configured such that a first insulating material layer is formed on one surface of a core layer in advance so that the first insulating material layer is filled in inner areas of a via hole and a chip mounting cavity in the core layer, thereby enabling shapes of the chip mounting cavity and the via hole to be maintained.

### Solution to Problem

According to an aspect of the present invention, there is provided a method of manufacturing a printed circuit board for mounting a chip, the method including: providing a chip mounting cavity in a core layer; mounting the chip to the chip mounting cavity; forming a first insulating material layer on one surface of the core layer to fill a space formed between the chip and the chip mounting cavity; and forming a second material layer of a different kind from the first insulating material layer on the one surface of the core layer.

According to another aspect of the present invention, there is provided a printed circuit board for mounting a chip, including: a core layer in which a chip mounting cavity is formed; a chip mounted to the chip mounting cavity; a space formed between the chip and the chip mounting cavity a first insulating material layer filled in the space; and a second insulating material layer formed on one surface of the core layer, wherein the first insulating material layer and the second insulating material layer are different kinds of members.

### ADVANTAGEOUS EFFECTS OF INVENTION

According to one exemplary embodiment, the first insulating material layer is formed on one surface of the core layer, and the second material layer of a different kind from that of the first insulating material layer is formed on a surface of the core layer so that the second insulating material layer is prevented from being non-uniformly formed on the surface of the core layer, thereby minimizing the generation of warpage.

According to one exemplary embodiment, the first insulating material layer composed of only resin without glass fabric is thermal-compressed on one surface of the core layer so that the second material layer formed on the core layer can be uniformly formed on the surface of the core layer.

According to one exemplary embodiment, the first insulating material layer is formed on one surface of the core layer in advance so that the first insulating material layer is filled in the space formed between the chip and the chip mounting cavity in the core layer, whereby the thicknesses from a second insulating material to another surface of the core layer in the areas in which the chip mounting cavity is formed and in which the chip mounting cavity is not formed are formed to be substantially identical with each other.

According to one exemplary embodiment of the present invention, the first insulating material layer is formed on one surface of the core layer in advance so that the first insulating material layer is filled in the inner areas of the via hole and the chip mounting cavity in the core layer, thereby enabling the shapes of the chip mounting cavity and the via hole to be maintained.

### BRIEF DESCRIPTION OF DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 and FIG. 2 are cross-sectional views illustrating a structure of a printed circuit board for mounting a chip according to a conventional art;

FIG. 3 is a flow chart illustrating the process order of a method of manufacturing a printed circuit board for mounting a chip according to one exemplary embodiment of the present invention;

FIG. 4 is a flow chart showing process 360 of FIG. 3 in detail; and

FIG. 5 is a cross-sectional view illustrating a structure of the printed circuit board for mounting the chip according to the one exemplary embodiment of the present invention.

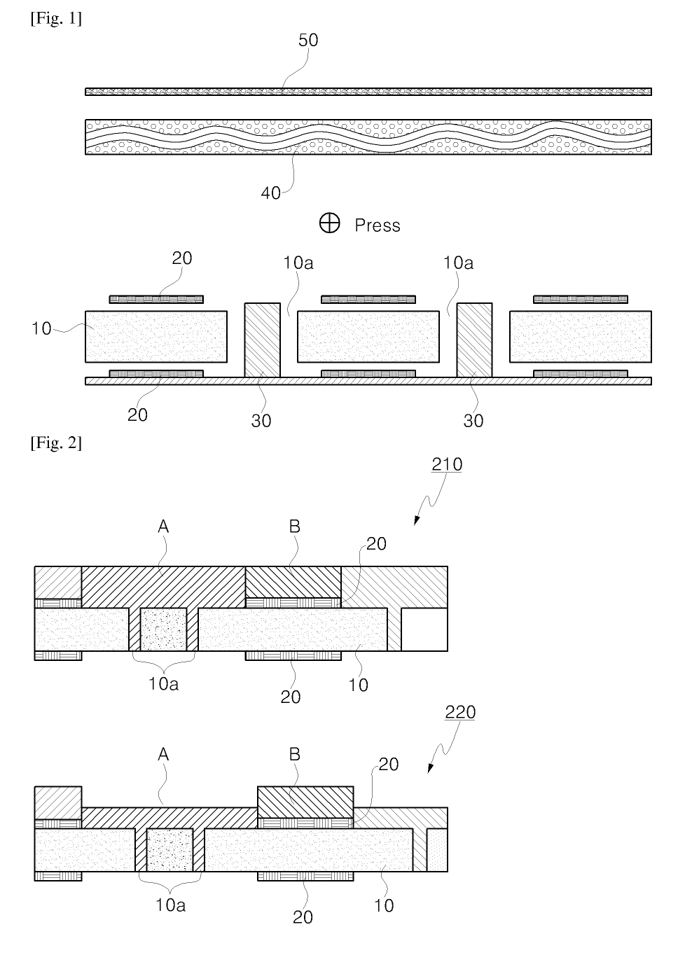

### BEST MODE FOR CARRYING OUT THE INVENTION

Exemplary embodiments according to the present invention will now be described more fully hereinafter with reference to the accompanying drawings. In the explanation with reference to the accompanying drawings, regardless of reference numerals of the drawings, like numbers refer to like elements through the specification, and repeated explanation thereon is omitted. Terms such as a first term and a second term may be used for explaining various constitutive elements, but the constitutive elements should not be limited to these terms. These terms is used only for the purpose for distinguishing a constitutive element from other constitutive element.

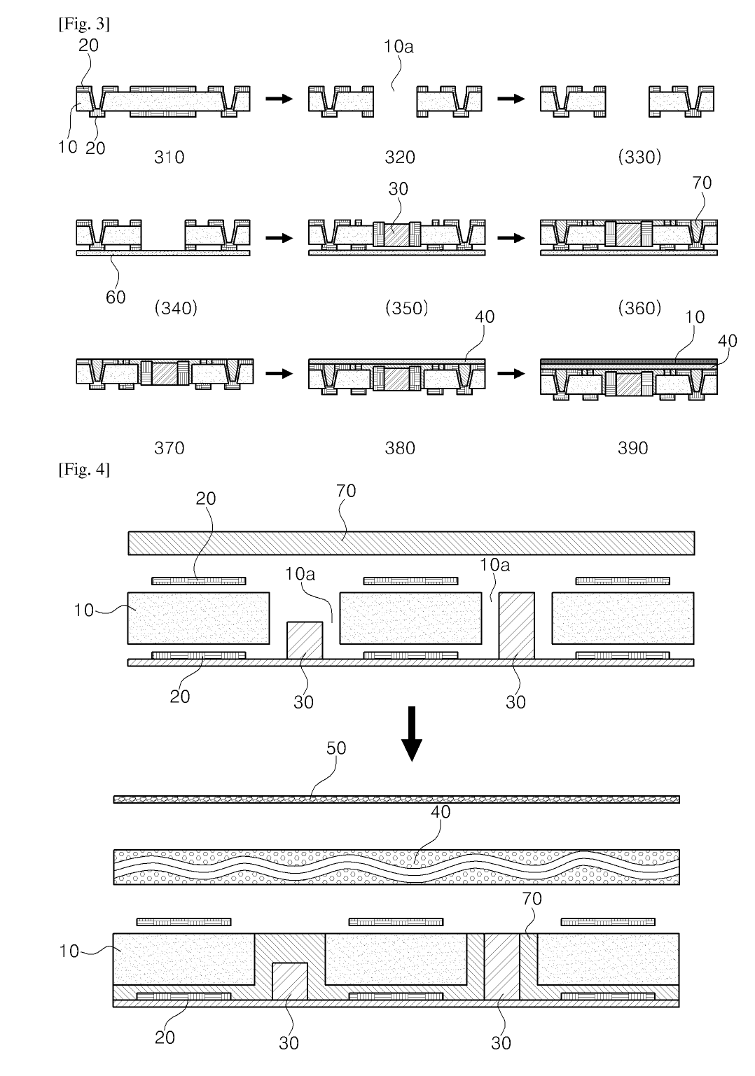

FIG. 3 is a flow chart illustrating a process order of a method of manufacturing a printed circuit board for mounting a chip according to one exemplary embodiment of the present invention.

Referring to FIG. 3, in step 310, a method of manufacturing a printed circuit board for mounting a chip includes forming circuit pattern layers 20 on one surface and another surface of a core layer 10, and forming a via hole 10b for connecting the circuit pattern layers 20 formed on the one surface and the another surface to each other. The method of manufacturing the printed circuit board for mounting the chip may include forming the circuit pattern layers 20 by performing an etching process.

In step 320, the method of manufacturing the printed circuit board for mounting the chip includes forming a cavity mounting cavity 10a in the core layer 10. the method of manufacturing the printed circuit board for mounting the chip includes forming the chip mounting cavity 10a using a router process or a drilling process to be consistent with a size of the chip to be mounted.

The method of manufacturing the printed circuit board for mounting the chip includes performing chemical treatment on one surface of the core layer 10 (330), and attaching an insulating film 60 to the another surface opposed to the one surface of the core layer 10 (340).

In step 350, the method of manufacturing the printed circuit board for mounting the chip includes mounting a chip 30 to the chip mounting cavity 10a.

In step 360, the method of manufacturing the printed circuit board for mounting the chip includes filling a space formed between the chip mounting cavity 10a and the chip 30 by forming a first insulating material 70 on the one surface of the core layer 10. Also, the method of manufacturing the printed circuit board for mounting the chip includes filling the inner areas of the chip mounting cavity 10a and the via hole 10b by forming the first insulating material layer 70 on the one surface of the core layer 10.

Even after the chip is mounted to the chip mounting cavity 10a, a void is bound to generate in the chip mounting cavity 10a. Furthermore, a void is also generated in the via hole 10b, thereby enabling the void to be filled with the first insulating material layer 70.

FIG. 4 is a flow chart showing process 360 of FIG. 3 in detail.

Referring to FIG. 4, the method of manufacturing the printed circuit board for mounting the chip includes forming the first insulating material layer 70 with a resin material including non glass fabric so as to be filled in the inner area of the chip mounting cavity 10a and the via hole 10b. The first insulating material layer 70 is formed to fill a void. If a resin material including glass fabric is used, resin and glass fabric are left on surfaces other than the inner part of the cavity due to the glass fabric, so a warpage problem, and bulge and dell problems are generated. Accordingly, in the present invention, the first insulating material layer 70 composed of only the resin material is formed on the one surface of the core layer 10.

Accordingly, the first insulating material layer 70 may not protrude to an outer part of the core layer 10, and may be filled to be present only in the inner areas of the chip mounting cavity 10a and the via hole 10b. At this time, the method of manufacturing the printed circuit board for mounting the chip may include thermal-compressing the first insulating material layer 70 on the one surface of the core layer 10 so that the first insulating material layer 70 can be inserted into the inner areas of the chip mounting cavity 10a and the via hole 10b in the core layer 10 (before being hardened). After the thermal-compressing (after being hardened), the method of manufacturing the printed circuit board for mounting the chip may include removing the first insulating material layer 70 remaining on the surface of the core layer 10.

Accordingly, thicknesses from the second insulating material layer 40 to another surface of the core layer 10 in the areas in which the chip mounting cavity 10a is formed and in which the chip mounting cavity 10a is not formed are substantially identical to each other.

The method of manufacturing the printed circuit board for mounting the chip is performed in such a manner that the insulating film 60 attached in step 340 is released (370), and the second insulating material layer 40 of a different kind of the first insulating material layer is formed on the surface of the core layer 10 (380). In the method of manufacturing the printed circuit board for mounting the chip, a second circuit pattern layer 50 may be formed on the second insulating material layer 40 (390).

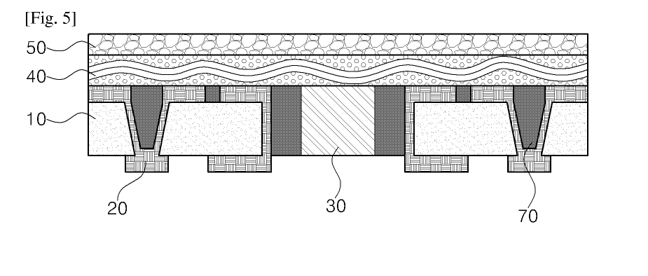

FIG. 5 is a cross-sectional view illustrating a structure of the printed circuit board for mounting the chip according to the one exemplary embodiment of the present invention.

Referring to FIG. 5, the printed circuit board for mounting the chip includes: the core layer 10 in which a chip mounting cavity is formed; the chip 30 mounted to the chip mounting cavity the space 30 formed between the chip and the chip mounting cavity the first insulating material layer 70 filled in the space; and the second insulating material layer 40 formed on one surface of the core layer 10, wherein the first insulating material layer 70 and the second insulating material layer 40 are different kinds of members.

The printed circuit board for mounting the chip may further include: circuit pattern layers 20 formed on the one surface and the another surface of the core layer 10; and the via hole for connecting the circuit pattern layers 20 formed on the one surface and the another surface to each other. At this time, the via hole may be filled with the first insulating material layer.

In a conventional printed circuit board for mounting a chip, the insulating material layer 40 formed on the one surface of the core layer 10 generates a difference in thickness according to positions between the areas in which the chip mounting cavity is formed and in which the chip mounting cavity is not formed. Accordingly, the difference in thickness is not generated according to the positions until the insulating material layer 40 is hardened 210 after the second insulating material layer 40 is formed, but after the second insulating material layer 40 is hardened, the difference in thickness is generated according the positions because the second insulating material layer 40 is filled in the void.

To solve this problem, in the present invention, the first insulating material layer 70, which is a different member from the second insulating material layer 40, is formed on the one surface of the core layer 10 in advance before the second insulating material layer 40 is formed so the first insulating material layer 70 can be filled in the void in the core layer 10. For this, the first insulating material layer 70 may be composed of the resin material including non glass fabric. If the resin material including glass fabric is used, resin and fabric are left on surfaces other than the inner part of the cavity due to the glass fabric, thereby generating a warpage problem and bulge and dell problems.

Accordingly, in the present invention, the first insulating material layer 70 composed of only a resin material is formed on the one surface of the core layer 10. The first insulating material layer 70 may be configured such that upper surface and lower surfaces thereof are formed smaller than upper and lower planes of the chip mounting cavity and the via hole. That is, the first insulating material layer 70 may be formed not to protrude to the outer part of the core layer 10. Accordingly, the first insulating material layer 70 may be completely removed from the surface of the core layer 10.

Accordingly, the thicknesses from the second insulating material 40 to the another surface of the core layer 10 in the areas in which the chip mounting cavity 10a is formed and in which the chip mounting cavity 10a is not formed are substantially identical with each other.

As an example, the printed circuit board for mounting the chip may further include the second circuit pattern layer 50 formed on the second insulating material layer 40.

As previously described, in the detailed description of the invention, having described the detailed exemplary embodiments of the invention, it should be apparent that modifications and variations can be made by persons skilled without deviating from the spirit or scope of the invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims and their equivalents. IN THE CLAIMS

1-13. (canceled)

14. A printed circuit board for mounting a chip, comprising;
a core layer including a chip mounting cavity;
a chip mounted into the chip mounting cavity;
a first insulating material layer filled in a space between the chip mounting cavity and the chip; and
a second insulating material layer laminated on one surface of the core layer.

15. The printed circuit board of claim 14, wherein the second insulating material layer is a different kind of insulating material layer from the first insulating material layer.

16. The printed circuit board of claim 14, wherein the first insulating material layer is made of a resin material of a non-glass fabric.

17. The printed circuit board of claim 14, wherein the first insulating material layer does not protrude to an outer part of the core layer.

18. The printed circuit board of claim 14, further comprising:
circuit pattern layers on one surface and the other surface of the core layer; and
a via hole connecting the circuit pattern layers.

19. The printed circuit board of claim 18, wherein the first insulating material layer is filled in the via hole.

20. The printed circuit board of claim 14, wherein thicknesses from the second insulating material layer to the other surface of the core layer in areas, in which the chip mounting cavity is formed, and in which the chip mounting cavity is not formed, are substantially identical to each other.

21. The printed circuit board of claim 14, further comprising a second circuit pattern layer formed on the second insulating material layer.
